(19) United States
(12) Patent Application Publication
(10) Pub. No.: US 2026/0334331 A1
(43) Pub. Date: Oct. 22, 2026

(54) PACKAGE STRUCTURE AND METHOD FOR MANUFACTURING THE SAME

(71) Applicant: JCET Management Co., LTD., Shanghai (CN)

(72) Inventor: Cheng YANG, Shanghai (CN)

(73) Assignee: JCET Management Co., LTD., Shanghai (CN)

(21) Appl. No.: 19/641,055

(22) Filed: Apr. 7, 2026

(30) Foreign Application Priority Data
Apr. 18, 2025 (CN) 202510492231.7

(51) Int. Cl. H10W 90/26; H10W 70/67; H10W 72/90; H10W 90/20

(52) U.S. Cl. CPC H10W 90/26; H10W 70/688; H10W 72/944; H10W 90/297

(57) ABSTRACT

A package structure and a manufacturing method are provided. The package structure includes a substrate a chip stacked structure on an upper surface of the substrate. The chip stacked structure includes sub-stacked units stacked in sequence along a first direction parallel to the upper surface of the substrate. Each of the sub-stacked units includes a sub-stacked body and a flexible interposer. The sub-stacked body includes first semiconductor chips stacked in sequence along the first direction. Adjacent first semiconductor chips are electrically connected. The sub-stacked body includes a first surface, a second surface, and a third surface. The second surface is perpendicular to the upper surface of the substrate, the third surface is parallel to the upper surface of the substrate, the first surface and the second surface of the sub-stacked body each include discrete external terminals electrically connect to the flexible interposer.

### CROSS-REFERENCE TO RELATED APPLICATIONS

This application claims the benefit of priority to Chinese Application No. 202510492231.7, filed on Apr. 18, 2025, which is incorporated herein by reference in its entirety.

### TECHNICAL FIELD

The present application relates to the field of package technology, and particularly relates to a package structure and a method for manufacturing the same.

### BACKGROUND

As chip miniaturization becomes increasingly difficult and the market's pursuit of high-performance chips remains undiminished, the industry has begun to explore breakthroughs in the field of package; in recent years, advanced IC package technologies such as 2.5D/3D have become a focal of attention for foundries, package and test factories, IDMs, chip design manufacturers and EDA manufacturers.

### SUMMARY

The present disclosure provides a package structure and a method for forming the same, which, when a plurality of semiconductor chips are stacked in sequence along a direction parallel to the upper surface of the substrate.

In an aspect, the embodiments of the present disclosure provide a package structure, which includes: a substrate, the substrate includes opposed upper surface and lower surface; and a chip stacked structure mounted on the upper surface of the substrate, the chip stacked structure includes a sub-stacked unit or includes a plurality of sub-stacked units stacked in sequence along a first direction, and the first direction is parallel to the upper surface of the substrate, and each sub-stacked unit includes a sub-stacked body and a flexible interposer, wherein the sub-stacked body includes a plurality of first semiconductor chips stacked in sequence along the first direction, and there are electrical connections between adjacent first semiconductor chips, and the sub-stacked body includes at least opposed first surface and second surface that are perpendicular to the upper surface of the substrate, as well as a third surface close to and parallel to the upper surface of the substrate, and the first surface and the second surface of the sub-stacked body have a plurality of discrete external terminals, and the flexible interposer electrically connects the external terminals on the first surface of the sub-stacked body to the third surface of the sub-stacked body, and the sub-stacked body is electrically connected with the substrate through the flexible interposer.

In some embodiments, the flexible interposer includes a first portion and a second portion that are connected with each other and electrically connected, and the flexible interposer further includes opposed fourth surface and fifth surface, and the fourth surface of the first portion of the flexible interposer is mounted on the first surface of the sub-stacked body and is electrically connected with the sub-stacked body, and the second portion of the flexible interposer is bent to a side of the third surface of the sub-stacked body, and the fourth surface of the second portion is adhered to the third surface of the sub-stacked body, and the fifth surface of the second portion is mounted on the upper surface of the substrate and is electrically connected with the substrate.

In some embodiments, the upper surface of the substrate has first solder pads, and the lower surface of the substrate has second solder pads, and the substrate has in it first connection lines, and the first connection lines are electrically connected with the first solder pads and the second solder pads.

In some embodiments, the flexible interposer includes a flexible redistribution layer.

In some embodiments, the flexible interposer includes a flexible circuit board.

In some embodiments, the fourth surface of the flexible interposer has third solder pads, and the fifth surface of the flexible interposer has fourth solder pads, and the flexible interposer has in it second connection lines, and the second connection lines are electrically connected with the third solder pads and the fourth solder pads.

In some embodiments, the second portion of the flexible interposer being electrically connected with the substrate includes: the fourth solder pads on the fifth surface of the second portion of the flexible interposer are electrically connected with the corresponding first solder pads on the upper surface of the substrate.

In some embodiments, the fourth solder pads on the fifth surface of the second portion of the flexible interposer are electrically connected with the corresponding first solder pads on the upper surface of the substrate through a wired and/or a wireless manner.

In some embodiments, the fourth solder pads on the fifth surface of the second portion of the flexible interposer being electrically connected with the corresponding first solder pads on the upper surface of the substrate through a wired manner includes: the fourth solder pads on the fifth surface of the second portion of the flexible interposer are electrically connected with the corresponding first solder pads on the upper surface of the substrate through first solder bumps.

In some embodiments, the fourth solder pads on the fifth surface of the second portion of the flexible interposer being electrically connected with the corresponding first solder pads on the upper surface of the substrate through a wireless manner includes: the fourth solder pads on the fifth surface of the second portion of the flexible interposer are electrically connected with the corresponding first solder pads on the upper surface of the substrate through an inductive coupling manner or a magnetic coupling manner.

In some embodiments, each of the first semiconductor chips in the sub-stacked body includes opposed active surface and back surface, and the active surface and the back surface are perpendicular to the upper surface of the substrate and perpendicular to the first direction, and the active surface has external connection solder pads, and the back surface has a through-hole connection structure.

In some embodiments, in the sub-stacked body, a plurality of first semiconductor chips being stacked in sequence along the first direction and having electrical connections includes: the back surface of a first semiconductor chip is correspondingly mounted on the active surfaces of adjacent first semiconductor chips along the first direction, and the through-hole connection structure on the back surface of a first semiconductor chip is electrically connected with the corresponding external connection solder pads on the active surfaces of the adjacent first semiconductor chips.

In some embodiments, the through-hole connection structure on the back surface of a first semiconductor chip being electrically connected with the corresponding external connection solder pads on the active surfaces of the adjacent first semiconductor chips includes: the through-hole connection structure on the back surface of a first semiconductor chip is electrically connected with the corresponding external connection solder pads on the active surfaces of the adjacent first semiconductor chips through second solder bumps.

In some embodiments, the through-hole connection structure on the back surface of a first semiconductor chip being electrically connected with the corresponding external connection solder pads on the active surfaces of the adjacent first semiconductor chips includes: the through-hole connection structure on the back surface of a first semiconductor chip is directly bonded with and electrically connected with the corresponding external connection solder pads on the active surfaces of the adjacent first semiconductor chips.

In some embodiments, the first portion of the flexible interposer being electrically connected with the sub-stacked body includes: the third solder pads on the fourth surface of the first portion of the flexible interposer are electrically connected with external connection solder pads on the active surface of a first semiconductor chip in the sub-stacked body.

In some embodiments, the third solder pads on the fourth surface of the first portion of the flexible interposer being electrically connected with external connection solder pads on the active surface of a first semiconductor chip in the sub-stacked body includes: the third solder pads on the fourth surface of the first portion of the flexible interposer are electrically connected with external connection solder pads on the active surface of a first semiconductor chip in the sub-stacked body through third solder bumps.

In some embodiments, when the chip stacked structure includes a plurality of sub-stacked units, there is no electrical connection between adjacent sub-stacked units.

In some embodiments, when the chip stacked structure includes a plurality of sub-stacked units, there are electrical connections between adjacent sub-stacked units.

In some embodiments, there being electrical connections between adjacent sub-stacked units includes: the adjacent sub-stacked units are electrically connected through the first portion of the flexible interposer.

In some embodiments, the adjacent sub-stacked units being electrically connected through the first portion of the flexible interposer includes: the through-hole connection structure on the back surface of a first semiconductor chip in the sub-stacked body of a sub-stacked unit is electrically connected with the fourth solder pads on the fifth surface of the first portion of the flexible interposer of the adjacent sub-stacked units through fourth solder bumps.

In some embodiments, it further includes: a second semiconductor chip mounted on the upper surface of the substrate on a side of the chip stacked structure, the second semiconductor chip is electrically connected with the substrate.

In some embodiments, the second semiconductor chip is electrically connected with the chip stacked structure through a part of the first connection lines in the substrate.

In another aspect, the present disclosure further provides a method for manufacturing a package structure, which includes: providing a substrate, the substrate includes opposed upper surface and lower surface; and providing a chip stacked structure, mounting the chip stacked structure on the upper surface of the substrate, the chip stacked structure includes a sub-stacked unit or includes a plurality of sub-stacked units stacked in sequence along a first direction, and the first direction is parallel to the upper surface of the substrate, and each sub-stacked unit includes a sub-stacked body and a flexible interposer, wherein the sub-stacked body includes a plurality of first semiconductor chips stacked in sequence along the first direction and electrically connected with each other, and the sub-stacked body includes at least opposed first surface and second surface that are perpendicular to the upper surface of the substrate, as well as a third surface close to and parallel to the upper surface of the substrate, and the flexible interposer includes a first portion and a second portion that are connected with each other and electrically connected, and the flexible interposer further includes opposed fourth surface and fifth surface, the fourth surface of the first portion of the flexible interposer is mounted on the first surface of the sub-stacked body and is electrically connected with the sub-stacked body, and the second portion of the flexible interposer is bent to a side of the third surface of the sub-stacked body, and the fourth surface of the second portion is adhered to the third surface, and the fifth surface of the second portion is mounted on the upper surface of the substrate and is electrically connected with the substrate.

In some embodiments, providing a chip stacked structure includes: providing a first carrier board; forming or mounting a plurality of discrete flexible interposers on the upper surface of the first carrier board, each flexible interposer includes a first portion and a second portion that are connected with each other and electrically connected, and the flexible interposer further includes opposed fourth surface and fifth surface, and the fifth surface contacts the upper surface of the first carrier board; providing a plurality of first semiconductor chips; stacking, on the fourth surface of the first portion of each flexible interposer, the plurality of first semiconductor chips in sequence along a direction perpendicular to the fourth surface, and forming a sub-stacked body on the fourth surface of the first portion, and there are electrical connections between adjacent first semiconductor chips in the sub-stacked body, and the sub-stacked body includes at least opposed first surface and second surface that are parallel to the fourth surface, as well as a third surface perpendicular to the fourth surface; and removing the first carrier board, and bending the second portion of each flexible interposer to a side of the third surface of the corresponding sub-stacked body, and adhering the fourth surface of the second portion to the third surface of the sub-stacked body, to form a plurality of discrete sub-stacked units.

In some embodiments, adhering the fourth surface of the second portion to the third surface of the sub-stacked body includes: adhering the fourth surface of the second portion to the third surface of the sub-stacked body through an adhesive layer.

In some embodiments, when the chip stacked structure includes a plurality of sub-stacked units stacked in sequence along a first direction, providing the chip stacked structure further includes: providing a second carrier board; stacking, on the upper surface of the second carrier board, the plurality of sub-stacked units in sequence along a direction perpendicular to the upper surface of the second carrier board to form the chip stacked structure, and during stacking, the second surface of the sub-stacked body in each sub-stacked unit faces the upper surface of the second substrate, and filing a third isolation layer between the plurality of sub-stacked units; and removing the second carrier board.

In some embodiments, the upper surface of the substrate has first solder pads, and the lower surface of the substrate has second solder pads, and the substrate has in it first connection lines, and the first connection lines are electrically connected with the first solder pads and the second solder pads; the fourth surface of the flexible interposer has third solder pads, and the fifth surface of the flexible interposer has fourth solder pads, and the flexible interposer has in it second connection lines, and the second connection lines are electrically connected with the third solder pads and the fourth solder pads.

In some embodiments, mounting the chip stacked structure on the upper surface of the substrate includes: forming first solder bumps on the surface of the fourth solder pads on the fifth surface of the second portion of the flexible interposer; orienting the fifth surface of the second portion of the flexible interposer in the chip stacked structure towards the upper surface of the substrate, and soldering the first solder bumps together with the corresponding first solder pads on the upper surface of the substrate.

In some embodiments, forming the first solder bumps on the surface of the fourth solder pads on the fifth surface of the second portion of the flexible interposer includes: providing a third carrier board; mounting the surfaces of the plurality of sub-stacked bodies in the chip stacked structure that are far away from the third surface onto the upper surface of the third carrier board; forming the first solder bumps on the surface of the fourth solder pads on the fifth surface of the second portion of the flexible interposer; and removing the third carrier board.

### BRIEF DESCRIPTION OF THE DRAWINGS

In order to explain the technical solutions of the embodiments of the present disclosure, the accompanying drawings required for the embodiments will be briefly introduced below, and it should be understood that the following accompanying drawings only illustrate certain embodiments of the present disclosure and should not be construed as limiting the scope, and for those ordinary skilled in the art, other relevant accompanying drawings can be obtained according to these accompanying drawings without inventive effort. Furthermore, in the following accompanying drawings, components are not necessarily drawn to scale, and components with similar related characteristics or features may have the same or similar accompanying drawing reference signs.

FIG. 1 is a structural schematic diagram of the package structure provided in some embodiments of the present disclosure; and

FIGS. 2-8 are structural schematic diagrams of various stages in the manufacturing method for the package structure provided in some embodiments of the present disclosure.

### DETAILED DESCRIPTION

In order to facilitate understanding of the present disclosure, a more comprehensive description of the present disclosure will be provided below with reference to the relevant accompanying drawings. The embodiments of the present disclosure are shown in the accompanying drawings. However, the present disclosure may be implemented in many different forms and is not limited to the embodiments described in the present article. On the contrary, the object of providing these embodiments is to make the disclosure of the present disclosure more thorough and comprehensive.

Unless otherwise defined, all technical and scientific terms used in the present article have the same meanings as those commonly understood by those skilled in the art belonging to the present disclosure. The terms used in the description of the present disclosure are only intended to describe the object of the specific embodiments and are not intended to limit the scope of the present disclosure.

In the description of the present disclosure, it should be noted that the use of words such as “first,” “second,” etc., to define objects (e.g., elements, components, areas, layers, doping types, and/or portions) is solely for the purpose of distinguishing different objects and does not used to describe a specific sequence or order, and unless the context clearly indicates otherwise, it should be understood that data used in this manner can be interchanged in appropriate circumstances.

In the description of the present disclosure, it should be understood that singular forms of “one,” “a,” and “the/this” may also include plural forms, unless otherwise indicated clearly in the context. It should also be understood that when terms “comprise” and/or “include” are used in this specification, the presence of the described features, integers, steps, operations, elements, and/or components can be determined, but the existence or addition of one or more other features, integers, steps, operations, elements, components, and/or groups are not excluded. Meanwhile, when used herein, the term “and/or” includes any and all combinations of the related listed items.

In the description of the present disclosure, it should also be noted that when a component is described as “on another component,” “connected to another component,” or “in contact with another component,” it may not only refer to a component being directly on another component, directly connected to another component, or directly in contact with this another component, but also refer to intermediate components may be inserted between a component and another component. Furthermore, “connection” includes not only fixed connection but also detachable connection or integral connection. Similarly, when an element is described as “electrically connected,” “in electrical contact,” “electrically coupled,” or “electrically coupled with” another element, this element and this another element may be in direct electrical contact or electrically coupled, or they may be in electrical contact or electrically coupled through intermediate elements.

In the description of the present disclosure, it should also be noted that the orientation or positional relationships indicated by directional words such as “front, rear, upper, lower, left, right,” “transversal, vertical, perpendicular, horizontal,” and “top, bottom” etc., are typically based on the orientation or positional relationships shown in the accompanying drawings, which are only used for the convenience of describing the present disclosure and simplifying the description, unless otherwise stated, these directional words do not indicate or imply that the referenced devices or elements must have a specific orientation or be constructed and operated in a specific orientation, therefore, they should not be understood as limiting the scope of protection of the present disclosure; the directional words "inside, outside" refer to the interior and exterior relative to the contour of respective components themselves.

Furthermore, in the description of the present disclosure, spatial relationship terms such as “below,” “under,” “subsequent to,” “beneath,” “above,” “on the upper surface,” “above the,” etc., herein may be used to describe the spatial positional relationship between an element or feature and other elements or features as shown in the figures. It should be understood that, in addition to the orientation shown in the figures, spatial relationship terms also include different orientations of elements or features during use and operation. For example, if the elements or features in the figures are flipped or inverted, the elements or features described as “under other elements,” “below them,” or “beneath them” will be oriented “on top of” other elements or features. Furthermore, elements may also include additional orientations (e.g., rotated by a certain angle or other orientations).

The structures of the embodiments of the present disclosure should not be limited to the specific shapes shown in the accompanying drawings of the description, but include shape deviations caused by, for example, manufacturing technologies.

It can be understood that in the accompanying drawings of the present disclosure, some adjacent film layers with the same processed film layer material in some figures are drawn as connected to make them similar to the actual structure.

3D package technology is the process of stacking different chips, such as CPUs, accelerators, memory, I/O, and power management, etc., to form a three-dimensional structure. The main advantages of 3D package technology include: 3D package technology makes a plurality of chips to be stacked together in sequence along a direction perpendicular to the substrate, so that the integration level and performance of the chips are improved; and compared to traditional planar connection methods, the total wiring length between chips is reduced to increase bandwidth and improve signal latency, so that the reliability and stability of the package structure are improved.

In existing 3D package technologies, a plurality of semiconductor chips are typically stacked in sequence along a direction perpendicular to the upper surface of the substrate, and this stacked method occupies a large substrate area and is not conducive to heat dissipation, consequently, a 3D package technology has emerged that makes a plurality of semiconductor chips to be stacked in sequence along a direction parallel to the upper surface of the substrate, which improves integration level, meanwhile facilitates heat dissipation for the stacked chips, and in this 3D package technology, when the semiconductor chips are electrically connected with the substrate, the side solder pads on the side surfaces of the semiconductor chips are soldered together with the corresponding side solder pads on the substrate, and this method may cause soldering defects such as cold solder joints, solder joint detachment, or solder bridging, etc., and affect the yield.

In addition, through research, it has been found that when a plurality of semiconductor chips are stacked in sequence along a direction parallel to the upper surface of the substrate, a problem exists that the side solder pads exposed on the side surfaces of the semiconductor chips may be non-coplanar or uneven, which causes the solder balls connected with the corresponding side solder pads, formed on the side surfaces of the stacked chip structure to be uneven in height, consequently, when solder balls on the side surfaces of the stacked chip structure are soldered together with the corresponding solder pads on the substrate, soldering defects such as cold solder joints, solder joint detachment, or solder bridging, etc. may occur, furthermore, as the number of stacked semiconductor chips increases, these defects become more severe, affecting yields.

The beneficial effects of the present disclosure include the following.

In the package structure and method for manufacturing the same of the present disclosure, the package structure includes: a substrate; and a chip stacked structure mounted on the upper surface of the substrate, the chip stacked structure includes a sub-stacked unit or includes a plurality of sub-stacked units stacked in sequence along a first direction, and the first direction is parallel to the upper surface of the substrate, and each sub-stacked unit includes a sub-stacked body and a flexible interposer, wherein the sub-stacked body includes a plurality of first semiconductor chips stacked in sequence along the first direction, and there are electrical connections between adjacent first semiconductor chips, and the sub-stacked body includes at least opposed first surface and second surface that are perpendicular to the upper surface of the substrate, as well as a third surface close to and parallel to the upper surface of the substrate, and the flexible interposer includes a first portion and a second portion that are connected with each other and electrically connected, and the flexible interposer further includes opposed fourth surface and fifth surface, the fourth surface of the first portion of the flexible interposer is mounted on the first surface of the sub-stacked body and is electrically connected with the sub-stacked body, and the second portion of the flexible interposer is bent to a side of the third surface of the sub-stacked body, and the fourth surface of the second portion is adhered to the third surface of the sub-stacked body, and the fifth surface of the second portion is mounted on the upper surface of the substrate and is electrically connected with the substrate. Due to the fact that the electrical connections between the plurality of first semiconductor chips in the sub-stacked units of the chip stacked structure and the substrate are all made through the flexible interposer rather than through side solder pads on the side surface of each first semiconductor chip, the fifth surface of the second portion of the flexible interposer is a flat surface (or the fifth surface has a high degree of flatness), therefore, when solder bumps (e.g., first solder bumps) are formed on the fifth surface, there will be no problem of uneven solder bumps, consequently, when the fifth surface of the second portion is mounted on the upper surface of the substrate and electrically connected with the substrate, the occurrence of soldering defects such as cold solder joints, solder joint detachment, or solder bridging, etc. can be reduced or avoided, which is conducive to improving yield. Moreover, compared to the method of directly stacking a plurality of first semiconductor chips to form a chip stacked structure, in the present disclosure, since the chip stacked structure may include a plurality of sub-stacked units stacked in sequence along a first direction, and each sub-stacked unit may include a sub-stacked body and a flexible interposer electrically connected with the sub-stacked body, and the sub-stacked body includes a plurality of first semiconductor chips stacked in sequence along the first direction, i.e., in the present disclosure, a plurality of first semiconductor chips may be distributed in a plurality of sub-stacked units, and each sub-stacked unit may be electrically connected with the substrate through a corresponding flexible interposer, the electrical connection between the chip stacked structure and the substrate is facilitated, and the occurrence of soldering defects such as cold solder joints, solder joint detachment, or solder bridging, etc. can be further reduced or avoided, and the yield is further improved.

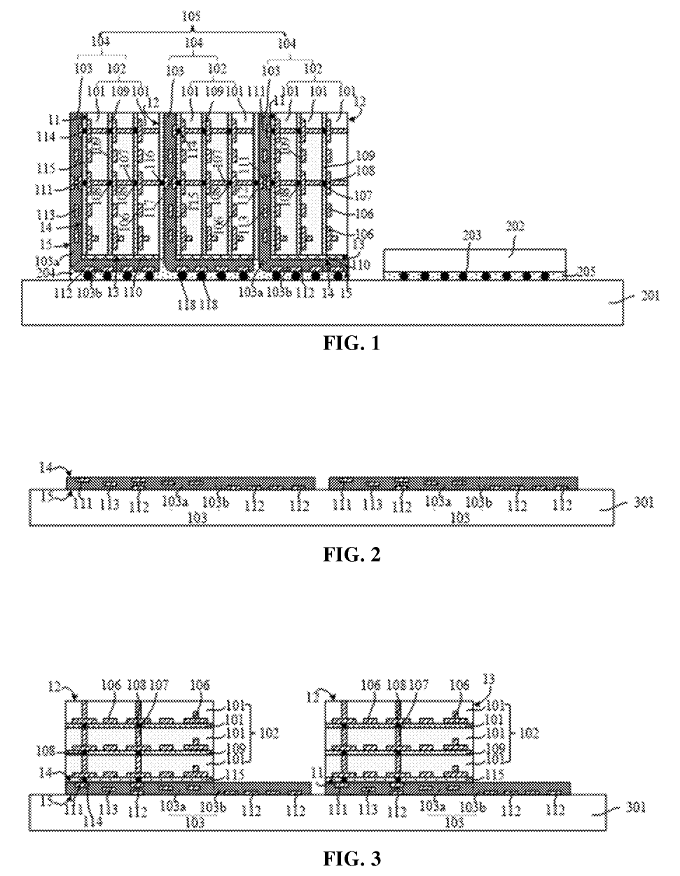

In order to solve the above problems, the embodiments of the present disclosure first provide a package structure. FIG. 1 is a structural schematic diagram of the package structure provided in some embodiments of the present disclosure.

Referring to FIG. 1, the package structure includes: a substrate 201, the substrate 201 includes opposed upper surface and lower surface; and a chip stacked structure 105 mounted on the upper surface of the substrate 201, the chip stacked structure 105 includes one or more sub-stacked units 104; when the chip stacked structure 105 includes a plurality of sub-stacked units, the plurality of sub-stacked units are stacked in sequence along a first direction, and the first direction is parallel to the upper surface of the substrate 201; each sub-stacked unit 104 includes a sub-stacked body 102 and a flexible interposer 103, wherein the sub-stacked body 102 includes a plurality of first semiconductor chips 101 stacked in sequence along the first direction, and electrical connections exist between adjacent first semiconductor chips 101; the sub-stacked body 102 includes at least opposed first surface 11 and second surface 12 that are perpendicular to the upper surface of the substrate 201, as well as a third surface 13 close to and parallel to the upper surface of the substrate 201; the first surface 11 and the second surface 12 of the sub-stacked body 102 have a plurality of discrete external terminals; the flexible interposer 103 electrically connects the external terminals on the first surface 11 of the sub-stacked body 102 to the third surface 13 of the sub-stacked body 102, and the sub-stacked body 102 is electrically connected with the substrate 201 through the flexible interposer 103.

In some embodiments, the flexible interposer 103 includes a first portion 103a and a second portion 103b that are connected with each other and electrically connected, and the flexible interposer 103 further includes opposed fourth surface 14 and fifth surface 15, and the fourth surface 14 of the first portion 103a of the flexible interposer 103 is mounted on the first surface 11 of the sub-stacked body 102 and is electrically connected with the sub-stacked body 102, and the second portion 103b of the flexible interposer 103 is bent to a side of the third surface 13 of the sub-stacked body 102, and the fourth surface 14 of the second portion 103b is adhered to the third surface 13 of the sub-stacked body 102, and the fifth surface 15 of the second portion 103b is mounted on the upper surface of the substrate 201 and is electrically connected with the substrate 201.

In some embodiments, the upper surface of the substrate 201 has first solder pads (not shown in the figure), and the lower surface of the substrate 201 has second solder pads (not shown in the figure), and the substrate 201 has in it first connection lines (not shown in the figure), and the first connection lines are electrically connected with the first solder pads and the second solder pads; in a specific example, the first solder pads, the second solder pads, and the first connection lines all include discrete multiple ones, and a part of the first connection lines may be used for the electrical connection between the first solder pads on the upper surface of the substrate 201 and the corresponding second solder pads on the lower surface of the substrate 201, and a part of the first connection lines may also be used for the electrical connection between a part of the first solder pads on the upper surface of the substrate 201, and a part of the first connection lines may also be used for the electrical connection between a part of the second solder pads on the lower surface of the substrate 201. A part of the first solder pads on the upper surface of the substrate 201 may be electrically connected with the chip stacked structure 105, and external solder bumps (not shown in the figure) may be formed on the second solder pads on the lower surface of the substrate 201, and the external solder bumps are used to be connected with other devices, other substrates, or package structures. The materials of the first solder pads, the second solder pads, and the first connection lines are metals, in some embodiments one or more of aluminum, copper, nickel, tin, titanium, tungsten, platinum, chromium, tantalum, gold, and silver. The material of the external solder bumps is tin or a tin alloy, and the tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

In some embodiments, the substrate 201 may be one of a resin substrate, a silicon substrate, a printed circuit board (PCB), a redistribution layer (RDL), a ceramic substrate, a glass substrate, or a flexible circuit board (FPC). In some embodiments, the substrate 201 may be a single-layer board or a multilayer board. In some embodiments, the substrate 201 may serve as an interposer.

In some embodiments, the chip stacked structure 105 may include only one sub-stacked unit 104. In other embodiments, the chip stacked structure 105 may include a plurality of sub-stacked units 104 (referring to FIG. 1), for example, the chip stacked structure 105 may include two, three, four, five, six, or more sub-stacked units 104, and the plurality of sub-stacked units 104 stacked in sequence along a first direction. It should be noted that the first direction is parallel to the upper surface of the substrate 201.

Each sub-stacked unit 104 includes a sub-stacked body 102 and a flexible interposer 103, and a sub-stacked body 102 includes a plurality of first semiconductor chips 101 stacked in sequence along the first direction, for example, a sub-stacked body 102 may include two, three, four, five, six, or more first semiconductor chips 101, and when the first semiconductor chips 101 are arranged in this manner, the occupied area on the upper surface of substrate 201 is relatively small, such that more other semiconductor chips may be mounted on the upper surface of substrate 201. A sub-stacked body 102 includes in it at least two first semiconductor chips 101, and there are electrical connections between adjacent first semiconductor chips 101. The sub-stacked body 102 is a cube, and the sub-stacked body 102 includes opposed first surface 11 and second surface 12 that are perpendicular to the upper surface of the substrate 201, as well as a plurality of side surfaces located between the first surface 11 and the second surface 12, and the plurality of side surfaces includes in them a third surface 13 that is close to and parallel to the upper surface of the substrate 201, and the first surface 11 of the sub-stacked body 102 has a plurality of discrete first external terminals, and the second surface 12 of the sub-stacked body 102 has a plurality of discrete second external terminals.

In some embodiments, each of the first semiconductor chips 101 in the sub-stacked body 102 includes opposed active surface and back surface, as well as four side surfaces located between the active surface and the back surface, and the active surface and the back surface are perpendicular to the upper surface of the substrate 201 and perpendicular to the first direction, and the active surface includes external connection solder pads 106, and the back surface includes a through-hole connection structure 107. In some embodiments, the active surface of the first semiconductor chip 101 also has a semiconductor device and a wiring layer connected with the semiconductor device, and the external connection solder pads 106 are electrically connected with the wiring layer, and the through-hole connection structure 107 is electrically connected with the semiconductor device or the wiring layer. The semiconductor device includes an active device, or includes an active device and a passive device, and the active device includes a transistor, and the passive device includes one or more of a resistor, a capacitor, an inductor, a ceramic resonator, a crystal resonator, and a transformer. The wiring layer includes an interlayer dielectric layer and metal lines located in the interlayer dielectric layer, and when the wiring layer is electrically connected with other structures, it is electrically connected with other structures through the metal lines.

In some embodiments, in the sub-stacked body 102, a plurality of first semiconductor chips 101 being stacked in sequence along a first direction and being electrically connected includes: the back surface of a first semiconductor chip 101 is correspondingly mounted on the active surface of an adjacent first semiconductor chip 101 along the first direction, and the through-hole connection structure 107 on the back surface of a first semiconductor chip 101 is electrically connected with the corresponding external connection solder pads 106 on the active surface of the adjacent first semiconductor chip 101. In a specific example, the first surface 11 of the sub-stacked body 102 is the active surface of a first semiconductor chip 101, and the first external terminals are the external connection solder pads 106, and the second surface 12 of the sub-stacked body 102 is the back surface of a first semiconductor chip 101, and the second external terminals are the through-hole connection structure 107.

In a specific example, the through-hole connection structure 107 on the back surface of a first semiconductor chip 101 being electrically connected with the corresponding external connection solder pads 106 on the active surface of an adjacent first semiconductor chip 101 includes: the through-hole connection structure 107 on the back surface of a first semiconductor chip 101 is electrically connected with the corresponding external connection solder pads 106 on the active surface of an adjacent first semiconductor chip 101 through second solder bumps 108, and a first isolation layer 109 is filled between the adjacent first semiconductor chips 101, and the material of the second solder bumps 108 includes solder, and the material of the first isolation layer 109 includes resin.

In another specific example, the through-hole connection structure 107 on the back surface of a first semiconductor chip 101 being electrically connected with the corresponding external connection solder pads 106 on the active surface of an adjacent first semiconductor chip 101 includes: the through-hole connection structure 107 on the back surface of a first semiconductor chip 101 is directly bonded with and electrically connected with the corresponding external connection solder pads 106 on the active surface of an adjacent first semiconductor chip 101, and the dielectric layer on the back surface of the first semiconductor chip 101 is bonded together with the dielectric layer on the active surface of the adjacent first semiconductor chip 101, i.e., the adjacent first semiconductor chips 101 are stacked using a hybrid bonding method.

The functions of the plurality of first semiconductor chips 101 in the sub-stacked body 102 are the same or different to meet the different functional and performance requirements of various package structures. In some embodiments, when the functions of the plurality of first semiconductor chips 101 are the same, the internal structures of the plurality of first semiconductor chips 101 are the same. In another embodiment, when the functions of the plurality of first semiconductor chips 101 are the same, the internal structures of the plurality of first semiconductor chips 101 are different.

According to the different functions, the first semiconductor chips 101 in the sub-stacked body 102 may include logic chips and/or memory chips. In some embodiments, the logic chips may include, but are not limited to, gate arrays, unit base arrays, embedded arrays, structured application-specific integrated circuits (ASICs), field-programmable gate arrays (FPGAs), complex programmable logic devices (CPLDs), graphics processing units (GPUs), central processing units (CPUs), microprocessor units (MPUs), microcontroller units (MCUs), logic integrated circuits (ICs), application processors (APs), display driver ICs (DDIs), radio frequency (RF) chips, power supply chips, or complementary metal-oxide-semiconductor (CMOS) image sensors. In some embodiments, the memory chips may include, but are not limited to, dynamic random-access memories (DRAMs), static random-access memories (SRAMs), magnetoresistive random-access memories (MRAMs), phase-change memories (PRAMs), resistive random-access memories (RRAMs), or non-volatile memory chips (such as flash memories).

In some embodiments, the functions of all first semiconductor chips 101 in the sub-stacked body 102 are the same. In a specific example, all first semiconductor chips 101 in the sub-stacked body 102 are memory chips. In another specific example, all first semiconductor chips 101 in the sub-stacked body 102 may also be logic chips.

In other embodiments, the functions of a part of the first semiconductor chips 101 in the sub-stacked body 102 are different from the functions of other parts of the first semiconductor chips 101. In a specific example, a part of the first semiconductor chips 101 in the chip stacked structure 100 are logic chips, and a part of the first semiconductor chips 101 are all memory chips. In another specific example, the first semiconductor chips 101 electrically connected with the flexible interposer 103 in the chip stacked structure 100 are logic chips, and a part of the first semiconductor chips 101 are all memory chips.

Each sub-stacked unit 104 further includes a flexible interposer 103 electrically connected with the sub-stacked body 102, and the flexible interposer 103 is used to transfer the first external terminals (e.g., external connection solder pads 106 on the active surface of the first semiconductor chip 101) of the first surface 11 of the sub-stacked body 102 to the third surface of the sub-stacked body 102, to facilitate electrical connection between the sub-stacked body 102 and the substrate 201. In some embodiments, the flexible interposer 103 may include a first portion 103a and a second portion 103b that are connected with each other and electrically connected, and the flexible interposer 103 further includes opposed fourth surface 14 and fifth surface 15, and the fourth surface 14 of the first portion 103a of the flexible interposer 103 is mounted on the first surface 11 of the sub-stacked body 102 and is electrically connected with the sub-stacked body 102, and the second portion 103b of the flexible interposer 103 is bent to a side of the third surface 13 of the sub-stacked body 102, and the fourth surface 14 of the second portion 103b is adhered to the third surface 13 of the sub-stacked body 102, and the fifth surface 15 of the second portion 103b is mounted on the upper surface of the substrate 201 and is electrically connected with the substrate 201. Due to the fact that the electrical connections between the plurality of first semiconductor chips in the sub-stacked units of the chip stacked structure and the substrate are all made through the flexible interposer 103 rather than through side solder pads on the side surface of each first semiconductor chip, the fifth surface 15 of the second portion 103b of the flexible interposer 103 is a flat surface (or the fifth surface 15 has a high degree of flatness), therefore, when solder bumps (e.g., first solder bumps 118) are formed on the fifth surface 15, there will be no problem of uneven solder bumps, consequently, when the fifth surface 15 of the second portion 103b is mounted on the upper surface of the substrate 201 and electrically connected with the substrate 201, the occurrence of soldering defects such as cold solder joints, solder joint detachment, or solder bridging, etc. can be reduced or avoided, which is conducive to improving yield. Moreover, compared to the method of directly stacking a plurality of first semiconductor chips to form a chip stacked structure, in the present disclosure, since the chip stacked structure may include a plurality of sub-stacked units stacked in sequence along a first direction, and each sub-stacked unit may include a sub-stacked body and a flexible interposer electrically connected with the sub-stacked body, and the sub-stacked body includes a plurality of first semiconductor chips stacked in sequence along the first direction, i.e., in the present disclosure, many first semiconductor chips may be distributed in a plurality of sub-stacked units, and each sub-stacked unit may be electrically connected with the substrate through a corresponding flexible interposer, the electrical connection between the chip stacked structure and the substrate is facilitated, and the occurrence of soldering defects such as cold solder joints, solder joint detachment, or solder bridging, etc. can be further reduced or avoided, and the yield is further improved.

In some embodiments, the fourth surfaces 14 of the first portion 103a and the second portion 103b of the flexible interposer 103 have third solder pads 111, and the fifth surfaces 15 of the first portion 103a and the second portion 103b of the flexible interposer 103 have fourth solder pads 112, and the flexible interposer 103 has in it second connection lines, and the second connection lines are electrically connected with the third solder pads 111 and the fourth solder pads 112, and the materials of the third solder pads 111, the fourth solder pads 112, and the second connection lines are one or more of Al, Cu, Ag, Au, Pt, Ni, Ti, TiN, TaN, Ta, TaC, TaSiN, W, WN, and WSi. In a specific example, the flexible interposer 103 includes a flexible redistribution layer, and the flexible redistribution layer includes a flexible resin layer and the fourth solder pads 112, the second connection lines, and the third solder pads 111 located in the flexible resin layer. In another specific example, the flexible interposer 103 includes a flexible circuit board, and the flexible circuit board includes a flexible board layer and the fourth solder pads 112, the second connection lines, and the third solder pads 111 located in the flexible board layer.

In some embodiments, the fourth surface 14 of the second portion 103b being adhered to the third surface 13 of the sub-stacked body 102 includes: the fourth surface 14 of the second portion 103b is adhered to the third surface 13 of the sub-stacked body 102 through an adhesive layer 110.

In some embodiments, the second portion 103b of the flexible interposer 103 being electrically connected with the substrate 201 includes: the fourth solder pads 112 on the fifth surface 15 of the second portion 103b of the flexible interposer 103 are electrically connected with the corresponding first solder pads on the upper surface of the substrate 201. In some embodiments, the fourth solder pads 112 on the fifth surface 15 of the second portion 103b of the flexible interposer 103 are electrically connected with the corresponding first solder pads on the upper surface of the substrate 201 through a wired and/or a wireless manner.

In a specific example, the fourth solder pads 112 on the fifth surface 15 of the second portion 103b of the flexible interposer 103 being electrically connected with the corresponding first solder pads on the upper surface of the substrate 201 through a wired manner includes: the fourth solder pads 112 on the fifth surface 15 of the second portion 103b of the flexible interposer 103 are electrically connected with the corresponding first solder pads on the upper surface of the substrate 201 through first solder bumps 118, and the material of the first solder bumps 118 includes solder.

In another specific example, the fourth solder pads 112 on the fifth surface 15 of the second portion 103b of the flexible interposer 103 being electrically connected with the corresponding first solder pads on the upper surface of the substrate 201 through a wireless manner includes: the fourth solder pads 112 on the fifth surface 15 of the second portion 103b of the flexible interposer 103 are electrically connected with the corresponding first solder pads on the upper surface of the substrate 201 through an inductive coupling manner or a magnetic coupling manner, in some embodiments, the fifth surface 15 of the second portion 103b of the flexible interposer 103 has a first coupling structure electrically connected with the fourth solder pads 112, and the upper surface of the substrate 201 has a second coupling structure electrically connected with the first solder pads, and the first coupling structure and the second coupling structure include coils, the first coupling structure and the second coupling structure transmit signals through an inductive coupling manner or a magnetic coupling manner.

In another specific embodiment, a part of the fourth solder pads 112 on the fifth surface 15 of the second portion 103b of the flexible interposer 103 are electrically connected with a corresponding part of the first solder pads on the upper surface of the substrate 201 through a wired manner, and another part of the fourth solder pads 112 on the fifth surface 15 of the second portion 103b of the flexible interposer 103 are electrically connected with another corresponding part of the first solder pads on the upper surface of the substrate 201 through a wired manner and/or a wireless manner.

In some embodiments, the first portion 103a of the flexible interposer 103 being electrically connected with the sub-stacked body 102 includes: the third solder pads 111 on the fourth surface 14 of the first portion 103a of the flexible interposer 103 are electrically connected with the external connection solder pads 106 on the active surface of a first semiconductor chip 101 in the sub-stacked body 102. In a specific example, the third solder pads 111 on the fourth surface 14 of the first portion 103a of the flexible interposer 103 being electrically connected with the external connection solder pads 106 on the active surface of a first semiconductor chip 101 in the sub-stacked body 102 includes: the third solder pads 111 on the fourth surface 14 of the first portion 103a of the flexible interposer 103 are electrically connected with the external connection solder pads 106 on the active surface of a first semiconductor chip 101 in the sub-stacked body 102 through third solder bumps 114, and a second isolation layer 115 is also filled between the fourth surface 14 of the first portion 103a of the flexible interposer 103 and the active surface of the first semiconductor chip, and the material of the third solder bumps 114 includes solder, and the material of the second isolation layer 115 includes resin.

In some embodiments, when the chip stacked structure 105 includes a plurality of sub-stacked units 104 stacked in sequence along the first direction, there may be no electrical connection between adjacent sub-stacked units 104, and the adjacent sub-stacked units 104 are isolated from each other by a third isolation layer. In other embodiments, the chip stacked structure 105 includes a plurality of sub-stacked units 104 stacked in sequence along the first direction, and electrical connections may exist between adjacent sub-stacked units 104 to meet the different functional and performance requirements of different package structures.

In some embodiments, there being electrical connections between adjacent sub-stacked units 104 includes: the adjacent sub-stacked units 104 are electrically connected through the first portion 103a of the flexible interposer 103. In a specific example, the adjacent sub-stacked units 104 being electrically connected through the first portion 103a of the flexible interposer 103 includes: a through-hole connection structure 107 on the back surface of a first semiconductor chip 101 in the sub-stacked body 102 of a sub-stacked unit 104 is electrically connected with fourth solder pads 112 on the fifth surface 15 of the first portion 103a of the flexible interposer 103 of an adjacent sub-stacked unit 104 through fourth solder bumps 116, and a third isolation layer 117 is fully filled between the back surface of a first semiconductor chip 101 in a sub-stacked body 102 of a sub-stacked unit 104 and the fifth surface 15 of the first portion 103a of the flexible interposer 103 of an adjacent sub-stacked unit 104, and the material of the fourth solder bumps 116 includes solder, and the material of the third isolation layer 117 includes resin.

In some embodiments, the structure further includes: a second semiconductor chip 202 mounted on the upper surface of the substrate 201 on a side of the chip stacked structure 105, and the second semiconductor chip 202 is electrically connected with the substrate 201. In a specific example, the second semiconductor chip 202 is flip-chip mounted on the upper surface of the substrate 201, and fifth solder bumps 203 on the second semiconductor chip 202 are soldered together with corresponding first solder pads on the upper surface of the substrate 201. In some embodiments, the second semiconductor chip 202 is electrically connected with the chip stacked structure 105 through a part of the first connection lines in the substrate 201, and communication and/or data transfer can be performed between the second semiconductor chip 202 and the chip stacked structure 105. In some embodiments, the second semiconductor chip 202 includes a CPU chip or a GPU chip.

In some embodiments, a first underfill layer 204 is also filled between the chip stacked structure 105 and the upper surface of the substrate 201. A second underfill layer 205 is also filled between the second semiconductor chip 202 and the upper surface of the substrate 201.

The present disclosure also provides a method for manufacturing a package structure. FIGS. 2-8 are structural schematic diagrams of various stages in the manufacturing method for the package structure provided in some embodiments of the present disclosure.

Referring to FIG. 8, the manufacturing method includes: providing a substrate 201, the substrate 201 includes opposed upper surface and lower surface; providing a chip stacked structure 105, mounting the chip stacked structure 105 on the upper surface of the substrate 201, the chip stacked structure 105 includes a sub-stacked unit 104 or includes a plurality of sub-stacked units 104 stacked in sequence along a first direction, and the first direction is parallel to the upper surface of the substrate 201, and each sub-stacked unit 104 includes a sub-stacked body 102 and a flexible interposer 103, wherein the sub-stacked body 102 includes a plurality of first semiconductor chips 101 stacked in sequence along the first direction and electrically connected with each other, and the sub-stacked body 102 includes at least opposed first surface 11 and second surface 12 that are perpendicular to the upper surface of the substrate 201, as well as a third surface 13 close to and parallel to the upper surface of the substrate 201, and the flexible interposer 103 includes a first portion 103a and a second portion 103b that are connected with each other and electrically connected, and the flexible interposer 103 further includes opposed fourth surface 14 and fifth surface 15, the fourth surface 14 of the first portion 103a of the flexible interposer 103 is mounted on the first surface 11 of the sub-stacked body 102 and is electrically connected with the sub-stacked body 102, and the second portion 103b of the flexible interposer 103 is bent to a side of the third surface 13 of the sub-stacked body 102, and the fourth surface 14 of the second portion 103b is adhered to the third surface 13, and the fifth surface 15 of the second portion 103b is mounted on the upper surface of the substrate 201 and is electrically connected with the substrate 201.

The process of providing the chip stacked structure 105 is described in detail below in some embodiments in conjunction with FIGS. 2-8.

First, referring to FIG. 2, a first carrier board 301 is provided; a plurality of discrete flexible interposers 103 are formed or mounted on the upper surface of the first carrier board 301, and each flexible interposer 103 includes a first portion 103a and a second portion 103b that are connected with each other and electrically connected, and the flexible interposer 103 also includes opposed fourth surface 14 and fifth surface 15, and the fifth surface 15 are in contact with the upper surface of the first carrier board.

In some embodiments, the fourth surface 14 of the flexible interposer 103 has third solder pads 111, and the fifth surface 15 of the flexible interposer 103 has fourth solder pads 112, and the flexible interposer 103 has in it second connection lines, and the second connection lines are electrically connected with the third solder pads 111 and the fourth solder pads 112.

In some embodiments, when the flexible interposer 103 is a flexible circuit board, the flexible interposer 103 is directly mounted on the upper surface of the first carrier board 301 through a temporary bonding layer.

In other embodiments, when the flexible interposer 103 is a flexible redistribution layer, the flexible interposer 103 is formed on the upper surface of the first carrier board 301, in some embodiments, a flexible resin layer is formed on the upper surface of the first carrier board 301; and the fourth solder pads 112, the second connection lines, and the third solder pads 111 are formed in the flexible resin layer. The flexible resin layer may be a multilayer structure.

The flexible interposer 103 formed by the aforementioned method has a flat fifth surface 15 and a fourth surface 14.

Next, referring to FIG. 3, a plurality of first semiconductor chips 101 are provided; a plurality of first semiconductor chips 101 are stacked in sequence along a direction perpendicular to the fourth surface 14 on the fourth surface 14 of the first portion 103a of each flexible interposer 103, and a sub-stacked body 102 is formed on the fourth surface 14 of the first portion 103a, and electrical connections exist between adjacent first semiconductor chips 101 in the sub-stacked body 102, and the sub-stacked body 102 includes at least opposed first surface 11 and second surface 12 that are parallel to the fourth surface 14, as well as a third surface 13 perpendicular to the fourth surface 14.

When the plurality of first semiconductor chips 101 are stacked in sequence along a direction perpendicular to the fourth surface 14, the first semiconductor chips 101 of the upper layer are electrically connected with the first semiconductor chips 101 of the lower layer through second solder bumps 108, in some embodiments, the corresponding external connection solder pads 106 on the active surfaces of the first semiconductor chips 101 of the upper layer are soldered together with the through-hole connection structure 107 on the back surface of the first semiconductor chips 101 of the adjacent lower layer through the second solder bumps 108, and a first isolation layer 109 is filled between adjacent first semiconductor chips 101, the corresponding external connection solder pads 106 on the active surfaces of the first semiconductor chips 101 of the bottommost layer are soldered together with the third solder pads 111 on the fourth surface 14 of the first portion 103a of the flexible interposer 103 through third solder bumps 114, and a second isolation layer 115 is also filled between the fourth surface 14 of the first portion 103a of the flexible interposer 103 and the active surface of the first semiconductor chip, and the materials of the second solder bumps 108 and the third solder bumps 114 include solder, and the materials of the first isolation layer 109 and the second isolation layer 115 include resin. In specific examples, when stacking a plurality of first semiconductor chips 101, a Thermal Compression (TC) bonding, Non-Conductive Film (NCF) (TC-NCF) process or a Mass Reflow bonding with Molded UnderFill (MR-MUF) process may be used.

In other embodiments, when stacking a plurality of first semiconductor chips 101, a hybrid bonding process may be used.

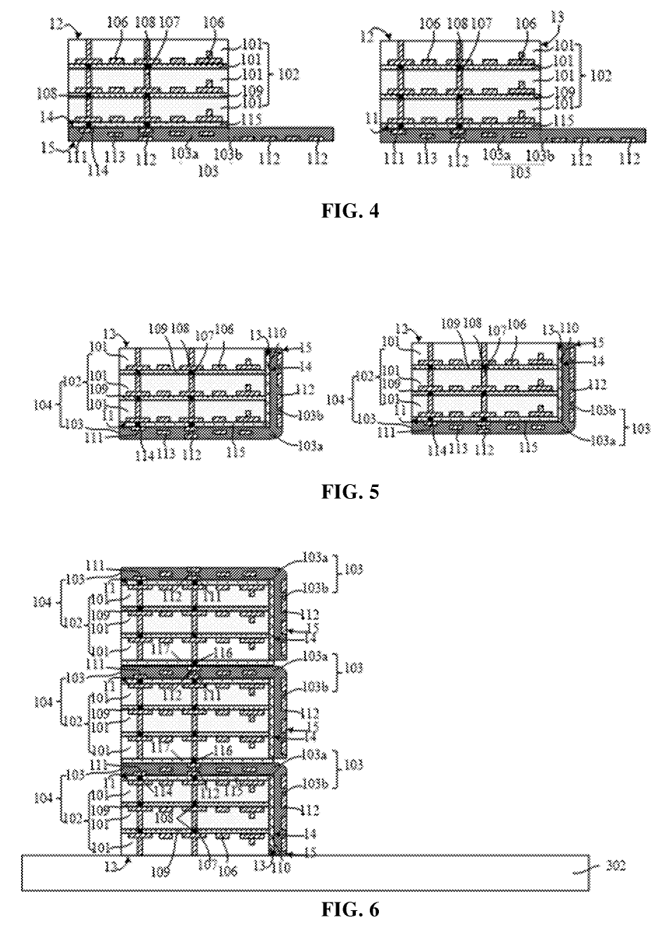

Next, referring to FIGS. 4 and 5, the first carrier board is removed, and the second portion 103b of each flexible interposer 103 is bent to a side of the third surface 13 of the corresponding sub-stacked body 102, and the fourth surface 14 of the second portion 103b is adhered to the third surface 13 of the sub-stacked body 102 to form a plurality of discrete sub-stacked units 104.

In some embodiments, the fourth surface 14 of the second portion 103b being adhered to the third surface 13 of the sub-stacked body 102 includes: the fourth surface 14 of the second portion 103b is adhered to the third surface 13 of the sub-stacked body 102 through an adhesive layer 110.

In the present disclosure, through the aforementioned steps, a plurality of discrete sub-stacked units 104 can be formed, and the manufacturing efficiency of the sub-stack units 104 is improved.

In some embodiments, when the chip stacked structure 105 includes a plurality of sub-stacked units stacked in sequence along a first direction, referring to FIG. 6, the chip stacked structure 105 further includes: providing a second carrier board 302; stacking, on the upper surface of the second carrier board 302, the plurality of sub-stacked units 104 in sequence along a direction perpendicular to the upper surface of the second carrier board 302 to form the chip stacked structure 105, and during stacking, the second surface 12 of the sub-stacked body 102 in each sub-stacked unit 104 faces the upper surface of the second carrier board 302, and filling a third isolation layer 117 between the plurality of sub-stacked units 104; and removing the second carrier board 302.

In some embodiments, mounting the chip stacked structure 105 on the upper surface of the substrate 201 includes: forming first solder bumps 118 on the surface of the fourth solder pads 112 on the fifth surface 15 of the second portion 103b of the flexible interposer 103; orienting the fifth surface 15 of the second portion 103b of the flexible interposer 103 in the chip stacked structure 105 towards the upper surface of the substrate 201, and soldering the first solder bumps 118 together with the corresponding first solder pads on the upper surface of the substrate 201.

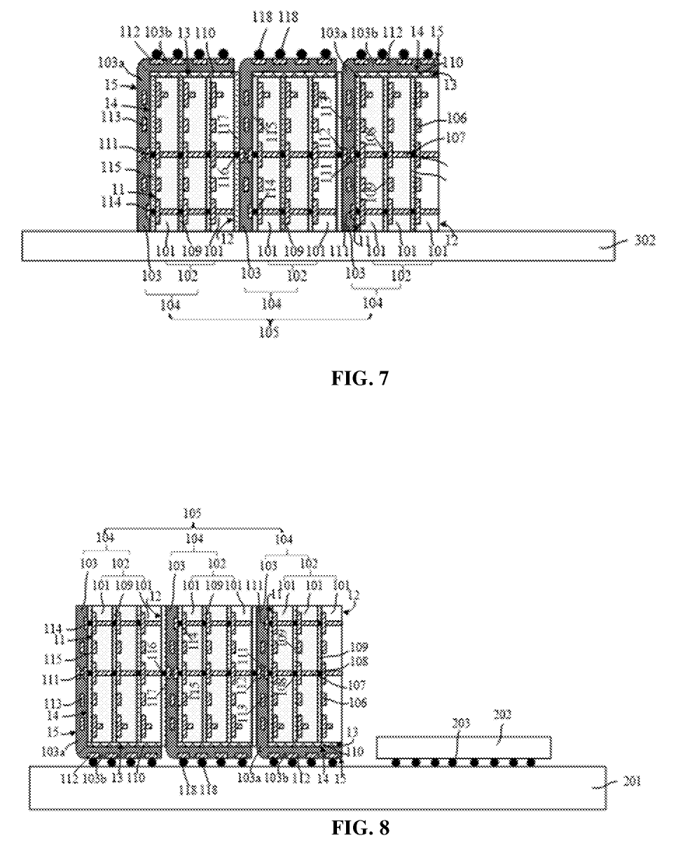

In an example, referring to FIGS. 7-8, forming the first solder bumps 118 on the surface of the fourth solder pads 112 on the fifth surface 15 of the second portion 103b of the flexible interposer 103 includes: providing a second carrier board 302; mounting the surfaces of the plurality of sub-stacked bodies 102 in the chip stacked structure 105 that are far away from the third surface 13 onto the upper surface of the second carrier board 302; forming the first solder bumps 118 on the surface of the fourth solder pads 112 on the fifth surface 15 of the second portion 103b of the flexible interposer 103; and removing the second carrier board 302.

In the description of the present specification, referential terms such as “some embodiments,” “other embodiments,” “ideal embodiments,” etc., indicate that specific features, structures, materials, or characteristics described in conjunction with the embodiments or examples are included in at least one embodiment or example of the present disclosure. In the present specification, illustrative descriptions of the aforementioned terms do not necessarily refer to the same embodiments or examples.

It should be noted that, in the case of no conflict, features in the various embodiments described above in the present disclosure may be combined with each other. Moreover, in the various embodiments described above, each embodiment focuses on describing its differences from other embodiments, and other specific descriptions of the same/similar portions between the various embodiments can be mutually referenced (or be referred to). Furthermore, in the above description, descriptions of well-known components and technologies have been omitted to avoid unnecessarily obscuring the concepts of the present disclosure.

Although the present disclosure has been disclosed above with some embodiments, they are not intended to limit the present disclosure; any person skilled in the art may make possible changes and modifications to the technical solutions disclosed herein without departing from the spirit and scope of the present disclosure, therefore, any simple modifications, equivalent changes, and refinements made to the above embodiments based on the technical essence of the present disclosure without departing from the content of the technical solutions of the present disclosure, shall fall within the scope of protection of the technical solutions of the present disclosure.

What is claimed is:

1. A package structure, comprising:
a substrate comprising an upper surface and a lower surface opposite to the upper surface; and
a chip stacked structure mounted on the upper surface of the substrate,
wherein the chip stacked structure comprises a plurality of sub-stacked units stacked in sequence along a first direction, and the first direction is parallel to the upper surface of the substrate,
wherein each of the plurality of sub-stacked units comprises a sub-stacked body and a flexible interposer,
wherein the sub-stacked body comprises a plurality of first semiconductor chips stacked in sequence along the first direction, and adjacent first semiconductor chips are electrically connected,
wherein the sub-stacked body comprises at least a first surface, a second surface opposite to the first surface, and a third surface, wherein the second surface is perpendicular to the upper surface of the substrate, the third surface is close to and parallel to the upper surface of the substrate, the first surface and the second surface of the sub-stacked body each comprise a plurality of discrete external terminals, and
wherein the flexible interposer electrically connects the external terminals on the first surface of the sub-stacked body to the third surface of the sub-stacked body, and the sub-stacked body is electrically connected to the substrate through the flexible interposer.

2. The package structure according to claim 1, wherein the flexible interposer comprises a first portion and a second portion connected and electrically connected to the first portion, wherein the flexible interposer further comprises a fourth surface and a fifth surface opposite to the fourth surface,
wherein the fourth surface of the first portion of the flexible interposer is mounted on the first surface of the sub-stacked body and is electrically connected to the sub-stacked body, the second portion of the flexible interposer is bent toward the third surface of the sub-stacked body, the fourth surface of the second portion is adhered to the third surface of the sub-stacked body, and the fifth surface of the second portion is mounted on and electrically connected to the upper surface of the substrate.

3. The package structure according to claim 2, wherein the flexible interposer comprises a flexible redistribution layer.

4. The package structure according to claim 2, wherein the flexible interposer comprises a flexible printed circuit board.

5. The package structure according to claim 3, wherein the fourth surface of the flexible interposer comprises third solder pads, the fifth surface of the flexible interposer comprises fourth solder pads, and the flexible interposer comprises second connection lines electrically connected to the third solder pads and the fourth solder pads.

6. The package structure according to claim 5, wherein the second portion of the flexible interposer being electrically connected to the substrate comprises:
the fourth solder pads on the fifth surface of the second portion of the flexible interposer are electrically connected to the corresponding first solder pads on the upper surface of the substrate.

7. The package structure according to claim 6, wherein the fourth solder pads on the fifth surface of the second portion of the flexible interposer are electrically connected to the corresponding first solder pads on the upper surface of the substrate through a wired connection, a wireless connection, or a combination thereof.

8. The package structure according to claim 7, wherein the fourth solder pads on the fifth surface of the second portion of the flexible interposer being electrically connected to the corresponding first solder pads on the upper surface of the substrate through the wired connection comprises:
the fourth solder pads on the fifth surface of the second portion of the flexible interposer are electrically connected to the corresponding first solder pads on the upper surface of the substrate through first solder bumps.

9. The package structure according to claim 7, wherein the fourth solder pads on the fifth surface of the second portion of the flexible interposer being electrically connected to the corresponding first solder pads on the upper surface of the substrate through the wireless connection comprises:
the fourth solder pads on the fifth surface of the second portion of the flexible interposer are electrically connected to the corresponding first solder pads on the upper surface of the substrate through inductive coupling or magnetic coupling.

10. The package structure according to claim 5, wherein each of the first semiconductor chips in the sub-stacked body comprises an active surface and a back surface opposite to the active surface, the active surface and the back surface are perpendicular to the upper surface of the substrate and perpendicular to the first direction, the active surface comprises external connection solder pads, and the back surface comprises a through-hole connection structure.

11. The package structure according to claim 10, wherein the first semiconductor chips being stacked in sequence along the first direction comprises:
the back surface of one of the first semiconductor chips is correspondingly mounted on the active surface of an adjacent one of the first semiconductor chips along the first direction, and the through-hole connection structure on the back surface of the one of the first semiconductor chips is electrically connected to the corresponding external connection solder pads on the active surface of the adjacent one of the first semiconductor chips.

12. The package structure according to claim 11, wherein the through-hole connection structure on the back surface of the one of the first semiconductor chips being electrically connected to the corresponding external connection solder pads on the active surface of the adjacent one of the first semiconductor chips comprises:
the through-hole connection structure on the back surface of the one of the first semiconductor chips is electrically connected to the corresponding external connection solder pads on the active surface of the adjacent one of the first semiconductor chips through second solder bumps.

13. The package structure according to claim 11, wherein the through-hole connection structure on the back surface of the one of the first semiconductor chips being electrically connected to the corresponding external connection solder pads on the active surface of the adjacent one of the first semiconductor chips comprises:
the through-hole connection structure on the back surface of the one of the first semiconductor chips is directly bonded to and electrically connected to the corresponding external connection solder pads on the active surface of the adjacent one of the first semiconductor chips.

14. The package structure according to claim 10, wherein the first portion of the flexible interposer being electrically connected to the sub-stacked body comprises:
the third solder pads on the fourth surface of the first portion of the flexible interposer are electrically connected to the external connection solder pads on the active surface of one of the first semiconductor chips in the sub-stacked body.

15. The package structure according to claim 14, wherein the third solder pads on the fourth surface of the first portion of the flexible interposer being electrically connected with the external connection solder pads on the active surface of the one of the first semiconductor chips in the sub-stacked body comprises:
the third solder pads on the fourth surface of the first portion of the flexible interposer are electrically connected to the external connection solder pads on the active surface of the one of the first semiconductor chips in the sub-stacked body through third solder bumps.

16. The package structure according to claim 10, wherein the chip stacked structure comprises a plurality of sub-stacked units, and there is no electrical connection between adjacent sub-stacked units.

17. The package structure according to claim 10, wherein the chip stacked structure comprises a plurality of sub-stacked units, and adjacent sub-stacked units are electrically connected to each other.

18. The package structure according to claim 17, wherein the adjacent sub-stacked units are electrically connected to each other comprises: the adjacent sub-stacked units are electrically connected through the first portion of the flexible interposer.

19. The package structure according to claim 18, wherein the adjacent sub-stacked units being electrically connected through the first portion of the flexible interposer comprises:
the through-hole connection structure on the back surface of one of the first semiconductor chips in the sub-stacked body of a first sub-stacked unit is electrically connected to the fourth solder pads on the fifth surface of the first portion of the flexible interposer of an adjacent second sub-stacked unit through fourth solder bumps.

20. The package structure according to claim 2, further comprising: a second semiconductor chip mounted on the upper surface of the substrate on a side of the chip stacked structure, wherein the second semiconductor chip is electrically connected to the substrate.
